(19) United States
(12) Patent Application Publication
(10) Pub. No.: US 2005/0026049 A1
(43) Pub. Date: Feb. 3, 2005

(54) Method for forming an opening on an alternating phase shift mask

(76) Inventors: Ralf Ziebold, Radebeul (DE); Gerhard Kunkel, Radebeul (DE)

Correspondence Address: SLATER & MATSIL, L.L.P., 17950 PRESTON RD, SUITE 1000, DALLAS, TX, 75252-5793, US

(21) Appl. No.: 10/870,699

(22) Filed: Jun. 17, 2004

(30) Foreign Application Priority Data
Jun. 18, 2003 (DE) 103 27 613.0

(51) Int. Cl. G03C 5/00; G03F 9/00

(52) U.S. Cl. 430/5; 430/322; 430/323; 430/324

(57) ABSTRACT

In a method of manufacturing a phase shift mask, an opening is produced by lithography in a second layer (32) arranged on an opaque layer (10). An etching step in which a first subregion (12) on a deep-etched surface of the transparent substrate (18) is uncovered is carried out in order for the opening to be transferred into the opaque layer (10) and into the substrate (18) below. Widening of the opening in the second layer (32) and etching so as to transfer the opening into the opaque layer (10) lead to the formation of a second subregion (14), which adjoins the recessed first subregion (12) and surrounds it in rim form, on the surface of the transparent substrate (18).

This application claims the benefit of German Patent Application No. 103 27 613.0, filed on Jun. 18, 2003, which application is hereby incorporated herein by reference.

### TECHNICAL FIELD

The invention relates to a method for forming a preferably square opening on an alternating phase shift mask, the opening having two subregions, which apply a different phase shift to a light beam which is incident on them.

### BACKGROUND

The invention relates in particular to a method for producing square openings on alternating phase shift masks, which can be used to pattern contact holes on semiconductor wafers in a lithographic projection step. The invention relates also, inter alia, to the formation of rim-type phase shift masks.

The lithographic patterning of contact hole levels to fabricate integrated circuits represents one of the major requirements involved in optical lithography. By way of example, in the case of memory products, contact connections for memory cells are to be produced on a very small surface area with a high positional accuracy and particularly small feature sizes. Within the memory cell arrays, the contact-hole openings that are to be formed in a layer on the wafer for this purpose take the form of a dense, regular grid, whereas, for example in the peripheral regions of a memory module, semi-isolated or fully isolated contact holes are to be formed in at times irregular arrangements.

Imaging errors, which may be caused, for example, by inaccuracies in the lens system, the lens aberration, lead to the imaging performance often differing with dense and isolated arrangements of contact-hole openings of very small feature sizes, which are formed jointly on a mask. In individual cases, for a given density of openings the projection system can be successfully adapted to the prevailing conditions, but imaging of isolated and dense structures at the same time results in a reduction in the size of what is known as the process window, in particular the depth of focus.

This particularly affects the imaging of the isolated contact-hole openings, especially since the settings of the projection system are often matched to the extremely critical contact-hole openings within dense arrays on the mask.

A solution has been discovered involving the use of attenuated phase shift masks for the imaging of contact-hole levels. The phase difference which is present as a result in each case at the transition from transparent regions to substantially opaque regions on the mask in this case advantageously increases the imaging contrast and therefore approximates the imaging behavior of dense contact-hole openings to that of isolated or semi-isolated contact-hole openings.

However, if attenuated phase shift masks are used, the problem arises whereby higher-order lens aberrations, such as for example the three-leaf clover effect, can lead to undesirable secondary effects.

Moreover, the problem of what is known as side lobe printing should be mentioned in this context, which problem can give rise to structure-forming secondary maxima in the image plane in the immediate vicinity of a structure, which is actually to be imaged.

Therefore, there has been a move toward the use of chromium-free or alternating phase shift masks to form contact holes. The contrast amplification at the edge of a contact hole is in this case effected by a narrow rim-like, phase-shifting region at the edge of the contact-hole opening. The basic principle is known from rim-type phase masks.

The width of the rim-like, phase-shifting region is matched, during the formation of the contact hole, to the result, which is to be achieved on the wafer during the imaging. This result in turn depends on the specific conditions (numerical aperture, exposure wavelength, resist properties, etc.) in the exposure apparatus used for the wafer exposure. Conventional methods provide for the rim to be formed with the aid of a mask writer. The minimum width of rim, which can be achieved is therefore dependent on the resolution limit of the mask writer.

### SUMMARY OF THE INVENTION

In one aspect, the present invention allows the production of contact-hole levels by means of alternating phase shift masks, wherein the differently phase-shifting subregions on the mask can be formed within an opening with a high degree of dimensional accuracy and preferably in sublithographic dimensions.

The preferred embodiment provides a method for forming a preferably square opening on an alternating phase shift mask, the opening having two subregions, which apply a different phase shift to a light beam which is incident on them, comprising the steps of providing a transparent substrate having a surface, an opaque layer arranged on the surface and at least a second layer, which is arranged on the opaque layer and in an etching process has a selective property with respect to the opaque layer in order to form an etching mask, forming an opening in the second layer, etching so as to transfer the opening into the opaque layer so that a first subregion on the surface of the transparent substrate is uncovered, further etching to transfer the opening from the opaque layer into the substrate down to a predetermined depth, which represents the difference in the phase shift, widening the opening in the second layer, etching so as to transfer the widened opening in the second layer into the opaque layer so that a second subregion, which adjoins the recess formed by the first subregion on the surface of the transparent substrate is uncovered, removing the second layer.

According to the preferred embodiment of the invention, the use of what is known as the spacer technique or an isotropic etching step makes it possible to produce a rim-like edge region in an opening on a mask, which is intended, for example, to form contact holes. By means of these techniques, an opening, which has already been formed in advance for the purpose of a first etching operation into a layer below, (e.g. quartz substrate and/or chromium) is widened in a controlled manner for a subsequent etching operation. The widening involves increasing the size of the opening in directions parallel to the layer planes on the mask. The length of the widening corresponds to the width of the rim, which is subsequently etched.

The second layer, which is arranged on the opaque layer, may be a resist layer or a layer of another material, which has a high etching selectivity with respect to the material of the opaque layer. The opaque layer preferably comprises chromium.

If the second layer is not a resist layer, it may in particular be a layer comprising silicon nitride, which has a sufficient etching selectivity with respect to the chromium of the opaque layer and with respect to the quartz. A resist layer, which can be used for lithographic patterning of the second layer, is once again to be provided on an etching-selective layer of this type.

The subregions of the opening to be produced that are to be uncovered in, or even etched into the substrate are defined by patterning of this second layer with subsequent transferal of the pattern into the opaque layer and—optionally—into the substrate. Therefore, the size of the subregions is in particular not defined in the chromium layer, as is the case in the prior art. It is preferable for only transferring, anisotropic etching steps to be carried out on the chromium layer.

The first subregion, which represents a recess to be etched into the quartz substrate, may, for example, be defined by means of a mask writer (e.g. electron beam or laser writer) in a resist layer, as second layer, arranged on the opaque layer. Alternatively, the region may also be exposed in a further resist layer arranged as oxide layer on the second layer and then transferred into the second layer in an etching step.

One significant step in the preferred embodiment of the invention involves widening the opening. Widening is achieved either by isotropic etching of the second layer or by removal of a spacer which was previously formed inside the edge of the opening in the second layer. In both cases, the diameter of the opening, as was present at the instant of a first etching step into the opaque layer, is subsequently increased. The variant involving forming and subsequently removing the spacer offers the particular advantage that the spacer material can be removed selectively over the material of the second layer, so that a steep edge profile without major degradation of the second layer is ensured. In the case of the isotropic etch, by contrast, it should be borne in mind that the second layer is also thinned at the same time, and consequently under unfavorable circumstances the border at the edge of the opening may also be degraded.

The widened opening offers the advantage that the uncovered opaque layer beneath it can then be removed in a dimensionally stable manner in an anisotropic etching step, with the result that this substrate surface is likewise uncovered by the corresponding etching step. The opening has then been formed in the second layer and in the opaque layer, and has as its basic area a central, recessed subregion and a rim-like, superficial subregion in the substrate. The difference in depth in the substrate corresponds to the desired phase difference, which is usually 180°.

The invention offers the particular advantage that both the spacer thickness and the removal of material in the isotropic etching operation can be controlled accurately in the respective deposition or etching process. However, both variables produce precisely the width of the rim, which is formed around the recess of the first subregion (or according to an advantageous configuration as an elevated region around a recess in the substrate). However, in this case in particular, deposition thicknesses or etching depths can be defined so accurately in their processes that it is even possible to achieve sublithographic structures with the aid of the spacer or etching technique.

It is therefore, possible to provide openings on masks for the production of contact holes with rim-like, phase-shifted edge regions, the width of which is less than the resolution limit defined by the respective lithographic exposure system used, i.e., the mask writer.

One particular advantage of the method consists in relaxing the required resolution of the mask writer by precisely double the width of the rim. Therefore, the mask writer only has to define the area of the first subregion.

According to a further aspect of the present invention, there is provision for the recessed subregion and the superficial subregion to be formed in an inverted arrangement, i.e., for the opening to be formed firstly as a rim in the second layer, then transferred into the opaque layer and into the quartz substrate. Only afterward is the material introduced retrospectively into the rim, as well as the opaque layer beneath it, removed in the region of the second layer within the region, which has been opened up in the form of a rim, so that a central, superficial region is uncovered on the substrate. This aspect is described in more detail in an exemplary embodiment.

According to this aspect too, the narrow, preferably sublithographic rim is formed using spacer technology, so that it is possible to achieve sublithographic dimensions for the width. However, the spacers are in this case not removed in order to widen the opening, but rather—as described—the opening inside the spacer is filled with a further filling material. Only then are the spacers removed, so as to uncover the rim of the opening.

### BRIEF DESCRIPTION OF THE DRAWINGS

The invention is now to be explained in more detail on the basis of an exemplary embodiment and with the aid of a drawing, in which:

FIG. 1 shows a plan view of a square opening which is to be formed by means of the method of the invention in order to define a contact hole;

FIG. 2 shows an intensity profile which can be produced with an opening produced in accordance with the invention in the image plane;

FIG. 3 shows a diagram in which the feature size produced on a wafer is plotted against the focus set in a projection apparatus;

FIGS. 4a-4f show an exemplary embodiment relating to the production of the opening in accordance with the prior art;

FIGS. 5a-5g show a first exemplary embodiment of the method according to the invention for producing the opening;

FIGS. 6a-6f show a second exemplary embodiment of the method according to the invention for producing the opening; and

FIGS. 7a-7h show a third exemplary embodiment of the method according to the invention for producing the opening using the spacer technique.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

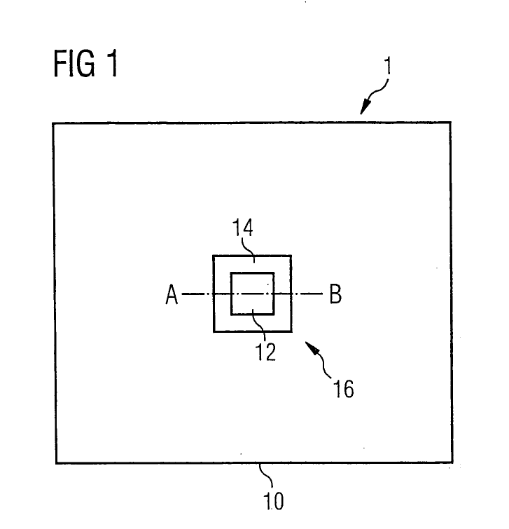

One example of a square opening on the mask in order to form a contact hole on a wafer, which includes a phase-shifting region at the edge, is illustrated in FIG. 1. In this plan view, it is possible to see a square opening 16, which is formed in an opaque layer 10 on the mask 1. The opening 16 comprises two transparent subregions 12, 14. A light beam, which impinges on these subregions and transmits them is in each case subjected to a phase shift. The particular phase shift differs by 180° between the subregions 12 and 14. In the case of chromium-free or alternating phase shift masks, the different phase shift is effected by etching into the substrate, e.g. quartz, to a depth which represents the difference in phase shift. The depth required to achieve this difference is dependent on the exposure wavelength and the transparent substrate material.

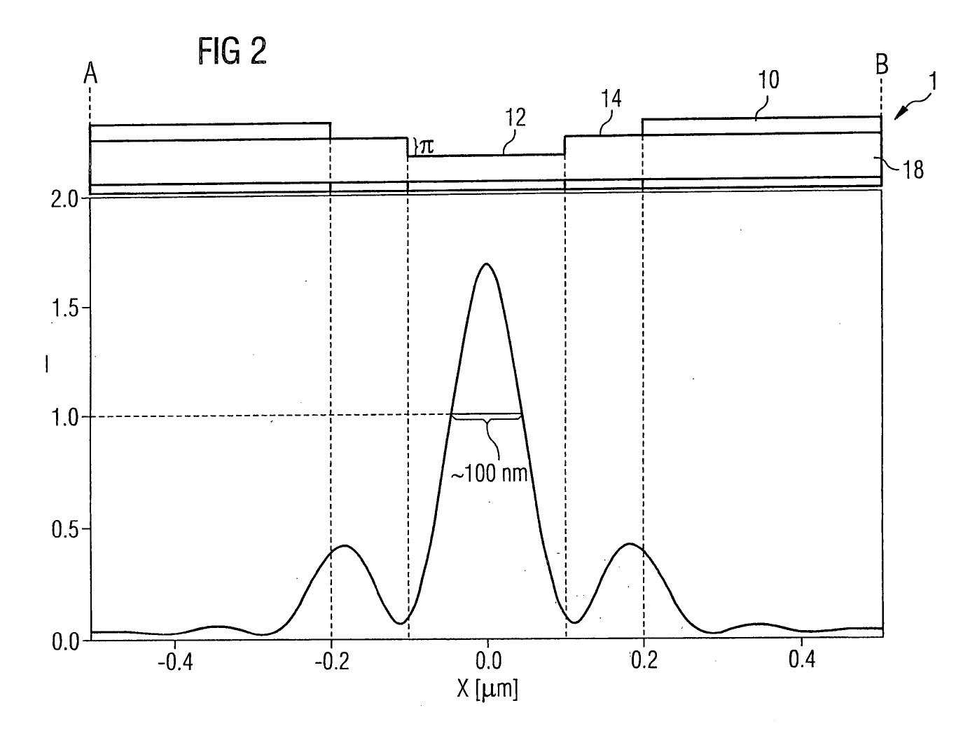

A cross-sectional profile on line AB indicated in FIG. 1 is illustrated in the upper part of FIG. 2. Reference symbol π denotes the quartz etching into the substrate 18, which is responsible for the phase shift difference.

The lower part of FIG. 2 shows an intensity profile of the light transmitting the square opening 16. The intensity is in this case given in system units. In the example, a square opening was predetermined on the mask in such a manner that an insulated contact-hole opening with an edge length of 100 nm is formed at an exposure wavelength 1=193 nm, a numerical aperture NA of 0.75 and a s=0.3. The intensity threshold, which when exceeded causes the resist to be exposed in a structure-forming manner on the laser, is approximately 1.0 in system units.

It can be seen from FIG. 2 that although the rim-like subregion 14 is not making a direct contribution, in accordance with the area which it takes up on the mask, to the area of the contact-hole opening formed on the wafer, it does, by virtue of phase extinction, produce a particularly strong contrast (steep curve) in the light component contributed by the subregion 12. The secondary maxima at +/−0.2 nm caused by the contributions of the subregion 14, meanwhile, do not reach the intensity threshold of 1.0 required for structures to be formed.

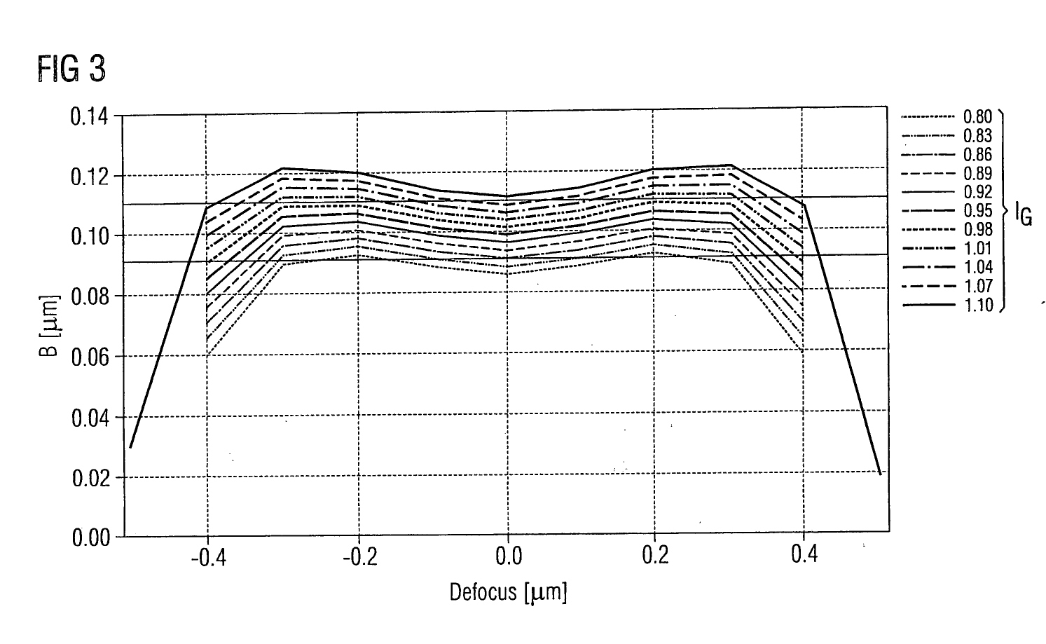

FIG. 3 shows that the contact-hole width of 100 nm+/−10 nm to be achieved can be maintained over a wider range of focus settings for various intensity thresholds for the intensity IG with the contact-hole opening based on the alternating phase mask concept. The Y axis in FIG. 3 denotes the contact-hole width which is in each case achieved on the wafer, whereas the X axis indicates the defocus. For an intensity threshold set at IG=0.95, above which a light beam impinging on the wafer just produces the formation of a structure, a satisfactory result within the given tolerance limits is achieved over a depth of focus range from −0.4 to +0.4.

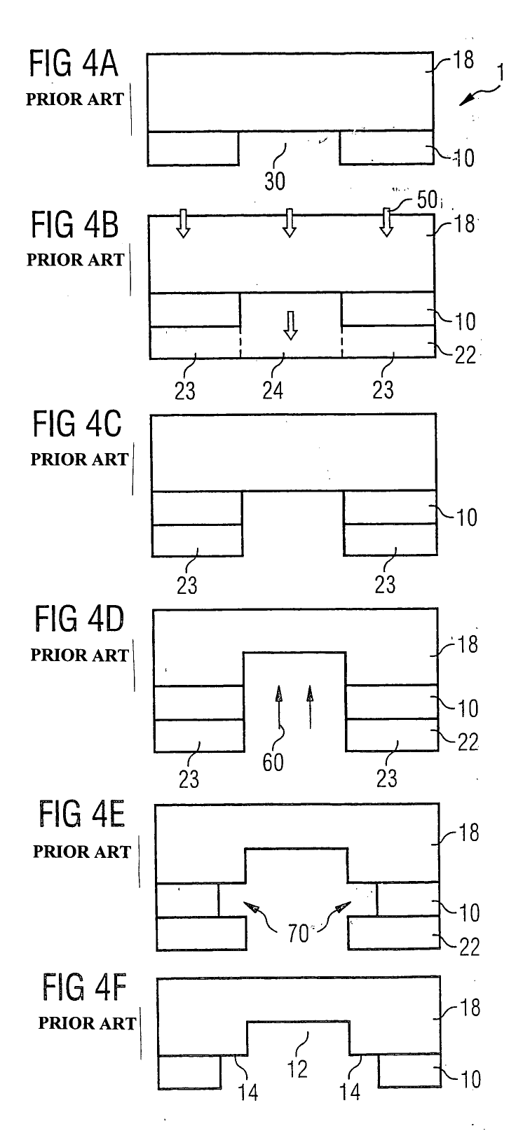

A method which can be used to produce the described contact-hole opening on an alternating phase mask is known, for example, from Yanagishita, Y., Ishiwata, N., Tabata, Y., Nakagawa, K., and Shigematsu, K., “Phase-Shifting Photolithography applicable to real IC Patterns”, SPIE VOL. 1463 Optical/Laser Microlithography IV (1991)/207. The method steps given in that document are illustrated in simplified form in FIG. 4.

FIG. 4a shows an alternating phase mask 1, comprising a substrate 18, on which an opaque layer 10, for example of chromium, is arranged. An opening 30 has already been formed in the opaque layer 10 during a lithographic patterning method.

Then, a photosensitive resist layer 22 is applied to the opaque layer 10 and into the opening 30, and back-surface floodlighting is carried out through the transparent substrate 18. The resist layer 22 on the front surface is not exposed in regions 23, on account of the shadowing action of the opaque layer 10, but is exposed in regions 24 inside and in front of the opening 30, as can be seen from FIG. 4b.

FIG. 4c shows the state after a developing step has been carried out, in which the exposed components 24 of the resist layer 22 have been removed.

FIG. 4d shows how a recess is etched into the substrate 18 using the unexposed but developed resist components 23 as an etching mask for a quartz etching step 60.

FIG. 4e shows the result of an isotropically executed etching process 70, which selectively removes the material of the opaque layer 10 in a direction parallel to the surface of the glass substrate 18. FIG. 4f shows the state after removal of the resist layer 22.

A method of this type has drawbacks, in that the floodlighting from the back surface means that the resist 22 on the front surface of the mask may not be exposed in a dimensionally stable manner, on account of reflections. In particular, however, the drawback arises whereby the opaque layer 10 cannot be etched back very deeply during the step of isotropic etching of the opaque layer 10 from the layer stack between the substrate 18 and the resist 22 without the resist layer 22 with the overhangs which are formed becoming unstable and possibly breaking off. Therefore, the cross-sectional profile of the opaque layer 10 cannot be controlled very successfully in a process sequence of this type.

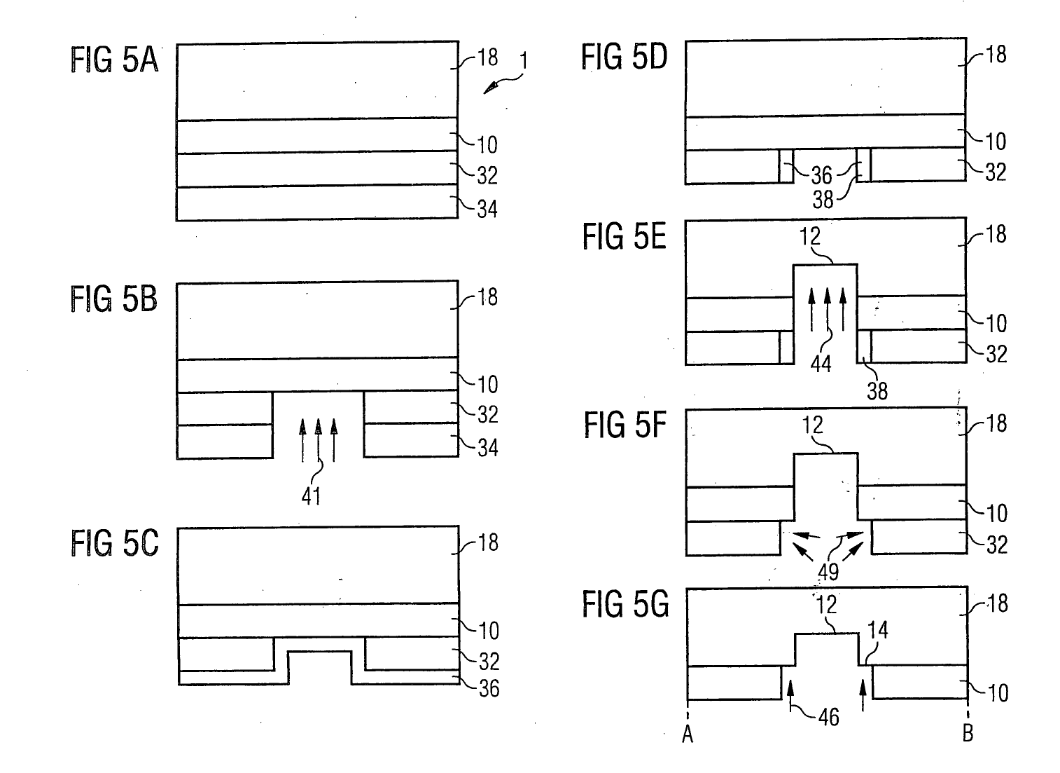

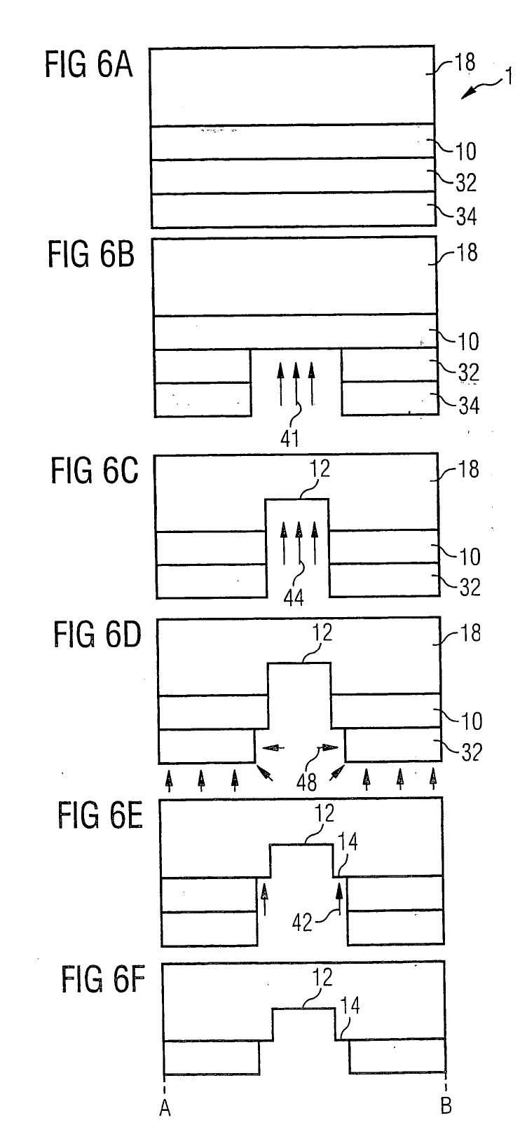

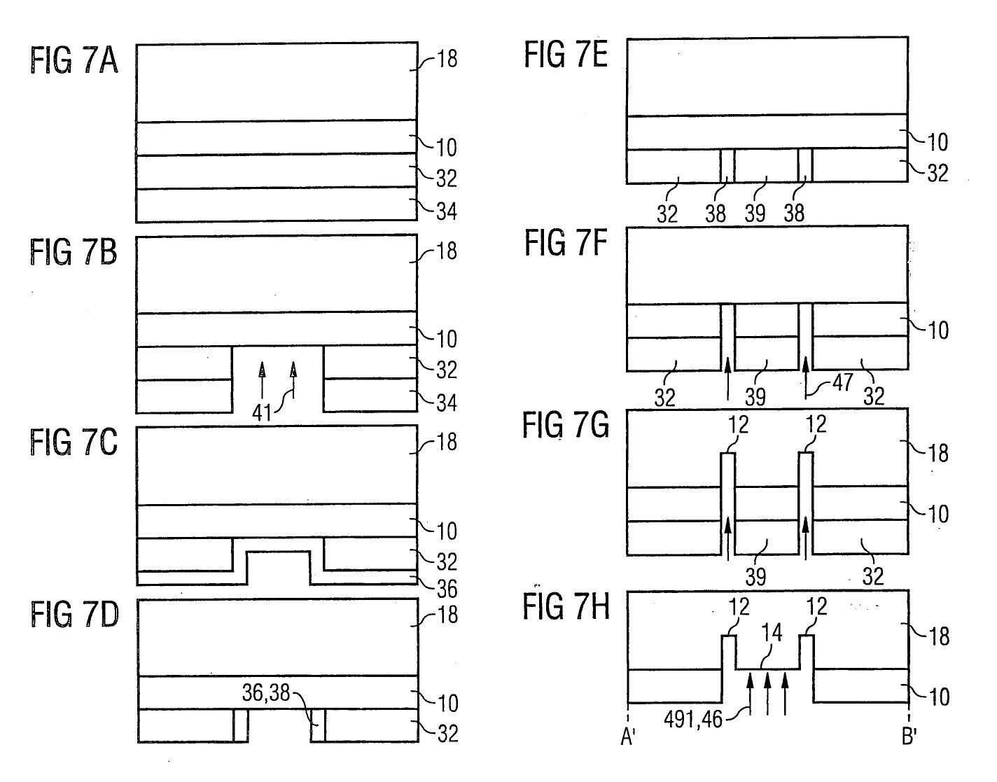

A method for producing an opening in accordance with the present invention will now be discussed with respect to FIGS. 5a-5g, which show various stages of forming a mask in accordance with a first exemplary embodiment. FIGS. 6a-6f and FIGS. 7a-7h show alternate embodiments.

Referring first to FIG. 5a, a starting state is shown. An opaque layer 10, for example a chromium layer, is arranged on a substrate 18, for example quartz, of the mask 1. A mask layer such as a silicon nitride layer (e.g., Si₃N₄) is arranged as second layer 32 on the chromium layer 10. A resist layer 34 is applied to the Si₃N₄ layer 32.

FIG. 5b shows the state after exposure of part of the resist layer 34, developing of the exposed part and transferring of the opening defined in this way into the Si₃N₄ layer 32.

FIG. 5c shows how a further layer 36 has been deposited conformally in the opening and on the Si₃N₄ layer 32 after removal of the exposed but as yet undeveloped parts of the resist 34. The further layer 36 comprises a material, which has a high selectivity in an etching process both with respect to the Si₃N₄ layer 32 and with respect to the opaque layer 10, e.g, the chromium. This material may, for example, be a doped oxide such as BSG (borosilicate glass) or an equivalent material.

The structure illustrated in FIG. 1 is to be produced in the exemplary embodiment. As can be seen from FIG. 2, the thickness of the rim-like second subregion on the uncovered substrate surface is 100 nm. The deposition process for the further layer 36 (e.g., the BSG layer), in terms of its duration and deposition rate, is set in such a way that the deposited thickness likewise reaches a value of about 100 nm.

FIG. 5d shows how, after the further layer 36 has been etched back in an anisotropic etching process, all that remains of this layer is the spacers 38 comprising the BSG material at the edge of the opening.

As shown in FIG. 5e, an etching process 44 is then carried out anisotropically, transferring the opening into the opaque layer 10 and into the quartz substrate 18. On account of the spacers 38, the opening in its current state has a reduced diameter compared to its original state (FIG. 5b).

FIG. 5f shows the state after removal of the spacer 38, for example in a selective etching process with respect to the material of the opaque layer 10 (chromium) and of the second layer 32 (BSG). The etching process may be isotropic or anisotropic. On account of this removal of the spacers 38, the opening is widened again. At the height of the second layer 32, the opening now has a larger diameter than the diameter of the opening in the opaque layer 10.

In a further anisotropic etching step 46, the widened opening is transferred into the chromium layer or opaque layer 10 until the surface of the substrate 18 is reached. The second layer 32 is then removed (FIG. 5g). This results in a transparent opening in the opaque layer 10 on the substrate 18, comprising a first subregion 12, formed in the quartz etching step 44, and a second subregion 14, uncovered in the anisotropic etching step 46. The subregions 12 and 14 differ by a depth by which the first subregion 12 has been etched into the quartz substrate 18. In the present case, the depth corresponds to a phase shift difference of 180° with respect to the light radiated onto a wafer to image the structures by a lithographic projection appliance.

A second exemplary embodiment is illustrated in FIG. 6. FIG. 6a corresponds to the starting state in FIG. 5a. The state illustrated in FIG. 6b also corresponds to the cross-sectional profile shown in FIG. 5b. The second layer 32 (e.g., Si₃N₄ layer) used in this example therefore has an opening, which has been transferred from the resist layer 34 in an etching step. As an alternative to the deposition of a further layer in order to form spacers, in this exemplary embodiment the simpler, but lower-quality, route of widening by means of isotropic etching of the second layer has been selected. For this purpose, as shown in FIG. 6c, first of all the first subregion 12 of the transparent opening is formed, in which the opening which has been transferred into the Si₃N₄ layer 32 is transferred further into the opaque layer 10 and, from there, anisotropically into the quartz substrate 18, in this case too producing a depth in the etching step 44 which represents the phase shift difference. The resist layer 34 is then removed.

After the isotropic etching step, which on the Si₃N₄ layer 32 is carried out selectively with respect to the opaque layer 10 and the glass substrate 18, has been implemented. The Si₃N₄ layer 32 firstly loses thickness, and secondly the opening formed therein is widened further, since the edge of the opening, in the etching step 48, is displaced back in the horizontal direction, i.e., parallel to the layer surfaces on the mask 1.

As shown in FIG. 6e, the thinned Si₃N₄ layer 32 is then used as etching mask for an anisotropic etching step 42, which transfers the widened opening into the opaque chromium layer 10. As a result, a rim-like subregion 14 is uncovered on the surface of the substrate 18 inside the opening. FIG. 6f shows the state after removal of the thinned Si₃N₄ layer 32. Reference symbols A and B in FIGS. 5-7 represent the section line as shown in FIGS. 1 and 2.

FIG. 7 shows a third exemplary embodiment of the present invention. FIGS. 7a and 7b once again correspond to the first process steps as illustrated in FIGS. 5a and 5b and FIGS. 6a and 6b.

The spacer technique is once again to be employed in this exemplary embodiment. Therefore, analogously to the process steps illustrated in FIGS. 5c and 5d first of all FIGS. 7c and 7d once again illustrate the process steps involved in forming the spacers 38.

As illustrated in FIG. 7e, a filler material 39, which is selective both with respect to the spacer 38 material (e.g., BSG) and with respect to the second layer 32 material (e.g., Si₃N₄), is introduced into the opening. The opening is delimited by the inner edge defined by the spacers 38. This further material may, for example, be chromium or molybdenum silicide.

The latter offers benefits in particular if the opaque layer comprises chromium. In this case, the person skilled in the art will naturally also consider the alternative option of forming a chromium layer 39 which is particularly thick compared to the chromium layer 10 (with the same thickness as the Si₃N₄ layer) as filler material 39, with the result that the chromium layer 10 is only removed beneath the position of what previously formed the spacers.

The surface is planarized back in order for the Si₃N₄ layer 32 and the spacers 38 to be uncovered again. The material of the spacer 38 is then etched out selectively, and the material of the Si₃N₄ layer 32 and the filler material 39 comprising chromium are used as etching mask for an anisotropic etching process 47 into the opaque layer 10, as illustrated in FIG. 7f.

FIG. 7g shows the continuation of the anisotropic etching step into the quartz substrate. As a result, a rim-like, first subregion 12 is formed in the glass substrate.

FIG. 7h shows the state after removal of the filler material 39, so that the opening is then widened inward in order, after an etching step 46 has been carried out, for removal of the opaque layer 10 on the surface of the substrate 18 inside the opening. The substrate surface, which is then uncovered, defines the second subregion 14, which has a phase shift difference of 180° with respect to the etched-in, narrow, rim-like subregions 12 when light is radiated onto them. To emphasize that the subregions 12 and 14 have been swapped over compared to the previous examples, in this case reference symbols A′ and B′ have been employed. They correspond to a FIG. 1 in which the reference symbols 12 and 14 have been swapped over.

Which of the two subregions is etched into the quartz and which merely superficially uncovers the substrate 18 is of only subordinate importance to the imaged intensity profile as shown in FIG. 2. As a result, it is possible for both subregions to be etched deeper into the substrate in order to compensate for any interference problem while maintaining the phase shift difference or the differences in depth in the substrate.

Although the present invention and its advantages have been described in detail, it should be understood that various changes, substitutions and alterations can be made herein without departing from the spirit and scope of the invention as defined by the appended claims.

1. A method for forming an opening on a mask, the method comprising:
providing a transparent substrate having a surface;
forming an opaque layer over the surface of the substrate;
forming at least a second layer over the opaque layer, the second layer capable of being etched selectively with respect to the opaque layer;
forming an opening in the second layer;
etching to transfer the opening into the opaque layer;
etching to transfer the opening from the opaque layer into the substrate down to a predetermined depth;
widening the opening in the second layer;
etching to transfer the widened opening in the second layer into the opaque layer; and
removing the second layer.

2. The method of claim 1 wherein the method of forming an opening comprises forming a square opening.

3. The method of claim 1 wherein the mask comprises an alternating phase shift mask that includes a first subregion and a second subregion, the first subregion comprising a portion of the substrate of the predetermined depth, boundaries of the first subregion having been defined during said etching to transfer the opening into the opaque layer and wherein the second subregion surrounds and adjoins the first subregion.

4. The method of claim 3 wherein the first and second subregions apply a different phase shift to a light beam which is incident on them.

5. The method of claim 4 wherein the predetermined depth represents a difference in the phase shift between the light transmitted through the first subregion and light transmitted through the second subregion.

6. The method of claim 1 wherein the widening step comprises an isotropic etching process that is applied selectively to the second layer.

7. The method of claim 1 wherein forming an opening in the second layer comprises:
etching a preliminary opening in the second layer;
conformally depositing a further layer over the second layer and in the preliminary opening; and
etching back the further layer so as to form a spacer inside the preliminary opening thereby forming the opening, the opening having a reduced diameter relative to the preliminary opening;
and
wherein widening the opening comprises removing the spacer selectively with respect to the opaque layer and the second layer.

8. The method of claim 1 wherein forming an opening in the second layer comprises:
etching a temporary opening in the second layer;
conformally depositing a further layer over the second layer and in the temporary opening;
etching back the further layer so as to form a spacer inside the temporary opening, with the result that the temporary opening has a reduced diameter;
depositing a filler material over the second layer and spacer and planarizing the filler material so as to fill the temporary opening; and
removing the spacer selectively with respect to the opaque layer and with respect to the filler material, so as to form the opening in the second layer;
and
wherein widening the opening comprises selectively removing the filler material.

9. The method of claim 8 wherein the filler material comprises chromium or molybdenum silicide.

10. The method of claim 1 wherein the second layer comprises a photosensitive resist.

11. The method of claim 1 wherein the second layer comprises silicon nitride.

12. The method of claim 11 wherein the second layer comprises Si₃N₄.

13. The method of claim 11 and further comprising applying a photosensitive resist over the second layer prior to forming the opening, and wherein forming the opening comprises exposing, developing and etching the photosensitive resist and then forming the opening in the second layer using the photosensitive resist as a mask.

14. The method of claim 1 wherein the opaque layer comprises chromium.

15. The method of claim 1 wherein the mask comprises a phase shift mask and wherein an amount by which the opening is widened is selected as a function of a resolution limit that can be achieved in an exposure apparatus for lithographic patterning of the phase shift mask, wherein the amount by which the opening is widened is less than the resolution limit.

16. The method of claim 1 wherein etching to transfer the opening into the opaque layer comprises anisotropic etching and wherein etching to transfer the opening from the opaque layer into the substrate comprises anisotropic etching.

17. The method of claim 1 wherein the etching to transfer the widened opening into the opaque layer comprises anisotropic etching.

18. A method of fabricating an integrated circuit using a mask formed using the method recited in claim 1, the method comprising performing an optical lithography process to form an opening in a layer disposed on a wafer.

19. A method of forming a mask, the method comprising:
providing a transparent substrate having a surface;
forming an opaque layer over the surface of the substrate;
forming at least a second layer over the opaque layer;
forming a preliminary opening in the second layer;
forming spacers along an inner surface of the preliminary opening so as to form a reduced-diameter opening within the preliminary opening;
performing an etching process to transfer a pattern of the reduced-diameter opening into the opaque layer and into the substrate;
removing the spacer; and
removing the second layer.

20. The method of claim 19 wherein forming spacers comprises:
conformally depositing a further layer; and
etching back the further layer.

21. The method of claim 19 wherein the second layer comprises silicon nitride.

22. The method of claim 19 wherein the opaque layer comprises chromium.

23. The method of claim 19 wherein the spacer comprises borosilicate glass.

24. A method of fabricating an integrated circuit using a mask formed using the method recited in claim 19, the method comprising performing an optical lithography process to form an opening in a layer disposed on a wafer.

25. A method of forming a mask, the method comprising:
providing a transparent substrate having a surface;
forming an opaque layer over the surface of the substrate;
forming at least a second layer over the opaque layer;
forming an opening in the second layer;
performing an etching process to transfer a pattern of the opening into the opaque layer and into the substrate;
widening the opening in the second layer by performing an isotropic etching step that etches the second layer selectively relative to the opaque layer and the substrate;
etching an exposed portion of the opaque layer using the second layer as a mask; and
removing remaining portions of the second layer.

26. The method of claim 25 wherein the second layer comprises silicon nitride.

27. The method of claim 25 wherein the opaque layer comprises chromium.

28. A method of fabricating an integrated circuit using a mask formed using the method recited in claim 25, the method comprising performing an optical lithography process to form an opening in a layer disposed on a wafer.

29. A method of forming a mask, the method comprising:
providing a transparent substrate having a surface;
forming an opaque layer over the surface of the substrate;
forming at least a second layer over the opaque layer;
forming a preliminary opening in the second layer;
forming a spacer along an inner surface of the preliminary opening so as to form a reduced-diameter opening within the preliminary opening;
filling the reduced-diameter opening with a filler material;
removing the spacer;
etching the opaque layer and the substrate at an area where the spacer was removed;
removing the filler material; and
removing remaining portions of the second layer.

30. The method of claim 29 wherein the filler material comprises a material that can be etched selectively with respect to the spacer and with respect to the second layer.

31. The method of claim 30 wherein the second layer comprises silicon nitride, wherein the spacer comprises a doped oxide, and wherein the further material comprises chromium or molybdenum silicide.

32. The method of claim 29 wherein the opaque layer comprises chromium.

33. The method of claim 32 wherein the filler material comprises chromium.

34. The method of claim 29 wherein filling the reduced-diameter opening with a filler material comprises:
depositing the filler material over the second layer and the spacer and within the reduced-diameter opening; and
planarizing the filler material.

35. The method of claim 19 wherein forming spacers comprises:
conformally depositing a further layer; and
etching back the further layer.

36. A method of fabricating an integrated circuit using a mask formed using the method recited in claim 29, the method comprising performing an optical lithography process to form an opening in a layer disposed on a wafer.
